(19) United States
(12) Patent Application Publication
(10) Pub. No.: US 2013/0277856 A1
(43) Pub. Date: Oct. 24, 2013

(54) METHOD FOR STABILIZING EMBEDDED SILICON

(71) Applicant: Shawn X. ARNOLD, San Jose, CA (US)

(72) Inventor: Shawn X. ARNOLD, San Jose, CA (US)

(73) Assignee: Apple Inc., Cupertino, CA (US)

(21) Appl. No.: 13/588,268

(22) Filed: Aug. 17, 2012

Related U.S. Application Data
(60) Provisional application No. 61/636,505, filed on Apr. 20, 2012.

(51) Int. Cl. H01L 21/56; G06F 17/50; H01L 23/28

(52) U.S. Cl. 257/774; 438/126; 703/14; 257/E21.502; 257/E23.116

(57) ABSTRACT

A method for disclosing an integrated circuit embedded in a resin is disclosed. In one embodiment, stabilizing vias can be formed within the resin and can couple to corresponding pads in the integrated circuit. The stabilizing vias can be used in areas prone to failure when the combined resin/integrated circuit is stressed or undergoes some amount of displacement. In one embodiment, the stabilizing vias can be non-functional vias that do not carry electrical signals or power to or from the integrated circuit.

### CROSS REFERENCE TO RELATED APPLICATIONS

This application claims priority to U.S. Provisional Patent Application No. 61/636,505, filed Apr. 20, 2012, and entitled “METHOD FOR STABILIZING EMBEDDED SILICON,” which is incorporated herein by reference in its entirety and for all purposes.

### FIELD OF THE DESCRIBED EMBODIMENTS

The described embodiments relate generally to embedded integrated circuits and more particularly to methods for stabilizing embedded integrated circuits and increasing their resistance to deformation and damage that may come from externally exerted stresses.

### BACKGROUND

Integrated circuits are typically formed on silicon wafers and oftentimes packaged in a plastic or ceramic body with contacts distributed on the outside of the body to couple power and signals to and from the device. The body protects the fragile integrated circuit and provides a way to mount the device to a supporting structure such as a printed circuit board. One drawback of this approach is that the amount of space required to support the combined printed circuit board and device can be substantial.

One technique to reducing the space requirements embeds the integrated circuit directly into a resin that in turn can protect and support the integrated circuit combining the objectives of both the plastic or ceramic package and the printed circuit board. These designs can be relatively thin. The thinner designs can save precious space in a product. In some embodiments, the resin can be as thin as 50 μm. These relatively thin resins, however, can easily deform and deflect when subjected to external pressures or forces. Without the protection of traditional plastic or ceramic packaging, the fragile integrated circuit can undergo fracture and failure when the placed under stress.

Therefore, what is needed is a way to enhance the strength of the integrated circuit embedded in a resin. More particularly a way is needed to increase resistance to fracturing and breaking, and increase circuit reliability without substantially increasing resin thickness

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIGS. 1A and 1B are block diagrams of an integrated circuit embedded within a resin.

FIG. 2 is another block diagram of a top view of an integrated circuit embedded in a resin.

FIGS. 3A and 3B are block diagrams of a system including an integrated circuit embedded in resin in accordance with one embodiment of the specification.

FIG. 4 is a detailed view of fracture region shown in FIG. 3.

FIGS. 5A and 5B illustrate different stabilizing vias showing their physical characteristics.

FIG. 6 is a flow chart of method steps 600 for providing stabilizing vias to enhance integrated circuit stability.

### DETAILED DESCRIPTION OF SELECTED EMBODIMENTS

Representative applications of methods and apparatus according to the present application are described in this section. These examples are being provided solely to add context and aid in the understanding of the described embodiments. It will thus be apparent to one skilled in the art that the described embodiments may be practiced without some or all of these specific details. In other instances, well known process steps have not been described in detail in order to avoid unnecessarily obscuring the described embodiments. Other applications are possible, such that the following examples should not be taken as limiting.

In the following detailed description, references are made to the accompanying drawings, which form a part of the description and in which are shown, by way of illustration, specific embodiments in accordance with the described embodiments. Although these embodiments are described in sufficient detail to enable one skilled in the art to practice the described embodiments, it is understood that these examples are not limiting; such that other embodiments may be used, and changes may be made without departing from the spirit and scope of the described embodiments.

Integrated circuits can sometimes be embedded within a printed circuit board (PCB) material instead of being separately packed in plastic or ceramic bodies. Typically, insulating portions of PCBs are made of any of a number of resin materials. Since integrated circuits are often manufactured on silicon wafers, the integrated circuit ultimately embedded in resin can be very thin; sometimes just barely thicker than the silicon wafer itself. The combined integrated circuit and resin object can be made relatively thin to save space in product designs. While the resin may add some protection to the otherwise unprotected integrated circuit, the resin may not be able to adequately protect the integrated circuit from external forces that can deform or fracture the integrated circuit.

In one embodiment, the integrated circuit can be made relatively stronger by adding stabilizing vias through the insulting portions of the resin to the integrated circuit. It should be noted that since the insulating portions of the PCB are typically made of a resin material, embodiments described will refer to these insulating portions as simply a resin. One of skill in the art would recognize that embodiments described can be applied to any suitable substrate, not just resinous materials. In one embodiment, the stabilizing vias can be isolated and not coupled to any signals on the integrated circuit. In other embodiment, the stabilizing vias can also couple to signals within the integrated circuit. In one embodiment, the stabilizing vias can be laser vias. The stabilizing vias can be arranged in areas of the silicon that are the most prone to failure. In one embodiment, the stabilizing vias can be arranged in an anchoring pattern that can be normal to the direction of most likely fracture.

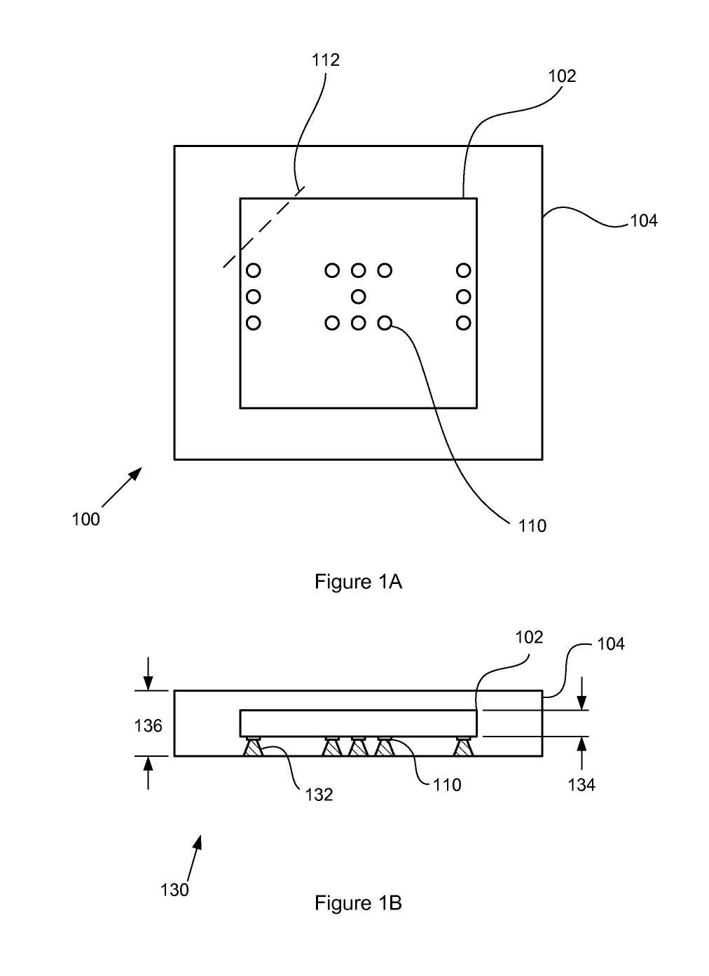

FIG. 1A is a block diagram 100 of a top view of integrated circuit 102 embedded within a resin 104. In this example, integrated circuit 102 can include one or more pads 110 disposed on one side. In other embodiments, pads 110 can be disposed on both sides of integrated circuit 102. Resin 104 typically is larger in all dimensions than silicon 102. FIG. 1B is a block diagram 130 of a side view of integrated circuit 102 embedded in resin 104. The integrated circuit thickness 134 can be relatively thin, oftentimes around 50 μm. Resin thickness 136 often need not be much greater than the integrated circuit thickness 134. In one embodiment, resin thickness 136 can be 100 μm. Side view of pad 110 is shown on integrated circuit 102. In one embodiment, vias 132 can be formed in resin 104 and can couple to pads 110. These vias 132 can allow signals to be coupled to and from integrated circuit 102 from outside resin 104.

While such a relatively thin combination of resin and integrated circuit can enable very slim overall product designs, integrated circuit 102 may not receive substantial support from resin 104. For example, some regions of integrated circuit 102 can experience deflection when the combination resin/integrated circuit undergoes stress or is exposed to external forces. Oftentimes, because of physical attributes of integrated circuit 102 and physical attributes of resin 104, some regions of the integrated circuit can be more prone to stress than others. If stress levels exceed a critical amount, then integrated circuit 102 can break or fracture. Fracture line 112 is shown in FIG. 1A. Fracture line 112 illustrates a possible break or fracture line in integrated circuit 102 where the integrated circuit may fail in response to an external force. In other embodiments, fracture line 112 can be located in other regions. In still other embodiments, integrated circuit 102 can include more than one fracture line. In this example, fracture line 112 shows a possible weak region due to, at least in part, the proximity of the corner of integrated circuit 102.

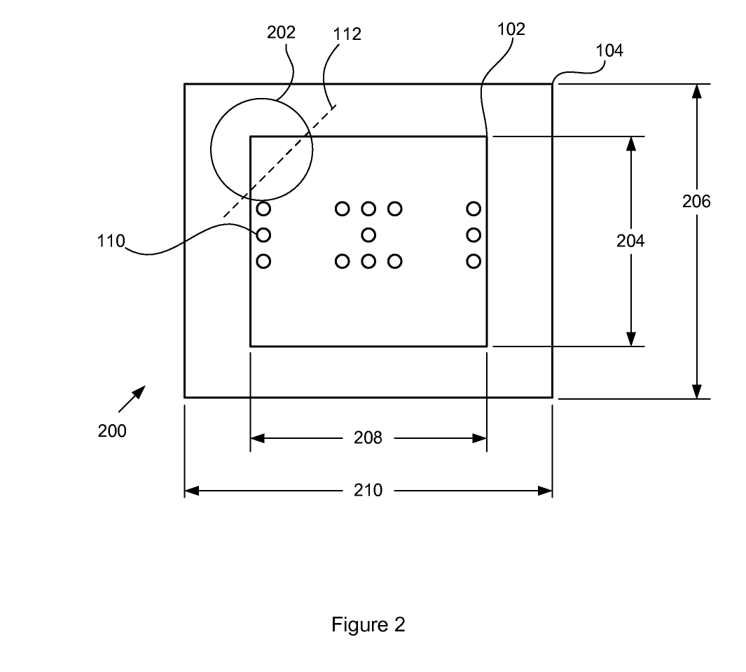

FIG. 2 is another block diagram 200 of a top view of an integrated circuit 102 embedded in resin 104. FIG. 2 highlights fracture region 202 on integrated circuit 102. In this example, fracture region 202 can include at least the region around fracture line 112. The fracture region 202 can denote a region on integrated circuit 102 that can experience relatively greater stresses or forces than other regions (i.e., the weak region described above). Although only one fracture region 202 is shown in FIG. 2, other fracture regions can exist substantially simultaneously with fracture region 202 on integrated circuit 102. Although shown in a region proximate to a corner in integrated circuit 102, fracture region 202 can exist anywhere on integrated circuit 102, particularly where the geometries of integrated circuit 102 can produce a relatively higher amount of stress.

Block diagram 200 also shows some physical attributes of integrated circuit 102 that can contribute to fracture region 202. Integrated circuit 102 can include integrated circuit length 208 and integrated circuit width 204. The length 208 and width 204 of integrated circuit 102 can have a direct effect on the relative strength of integrated circuit 102. For example, in one embodiment, the larger the overall length 208 or width 204 of integrated circuit 102, the larger the fracture area 202 can be. In other words, the fracture area 202 can be larger if the geometries of the integrated circuit 102 permit greater forces or stresses to be concentrated in certain regions.

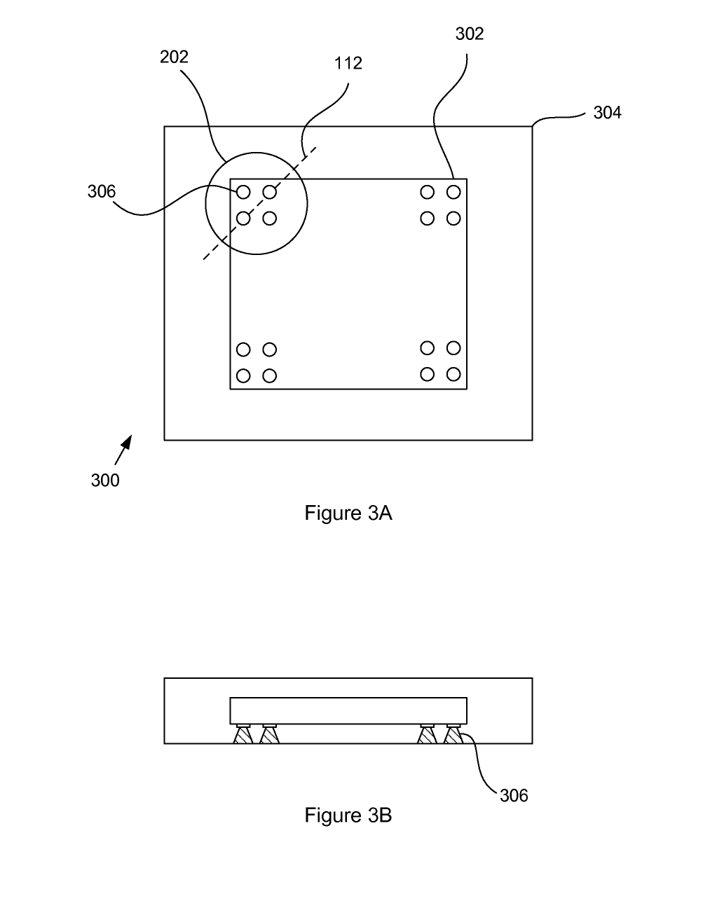

FIGS. 3A and 3B are block diagrams a system 300 including an integrated circuit 302 embedded in resin 304 in accordance with one embodiment of the specification. FIG. 3A is a simplified block diagram of a top view of the integrated circuit 302/resin 304 combination. In this example, fracture line 112 exists in at least one corner of integrated circuit 302 and is included in fracture region 202. In one embodiment, stabilizing vias 306 can be added to within the fracture region 202 to help add support to integrated circuit 102. FIG. 3B is a side view of the integrated circuit 302/resin 304 combination. Stabilizing vias 306 are also shown. FIGS. 3A and 3B are simplified such that only stabilizing vias 306 are shown for clarity; other vias were omitted.

Stabilizing vias 306 can be formed by arranging pads on integrated circuit 302 before begin embedded into resin 304. Then, after integrated circuit 302 is embedded in resin 304, stabilizing vias 306 can be formed in resin 304 and bonded to corresponding pads on integrated circuit 304. In one embodiment, stabilizing vias 306 can be laser vias. The stabilizing vias 306 can help to stabilize and anchor the fracture region 202 with respect to resin 304. In one embodiment, the stabilizing vias 306 can enhance a bond between resin 304 and integrated circuit 302 especially in fracture region 202. Improving the bond between resin 304 and integrated circuit 302 within fracture region 202 can add support to the integrated circuit 302 in the fracture region 202.

In one embodiment, stabilizing vias 306 can be non-functional vias. That is, although disposed on integrated circuit 302, stabilizing vias 306 need not carry any electrical signals or power. Stabilizing vias 306 can be advantageously placed anywhere on integrated circuit 302 since they need not be functional. In another embodiment, stabilizing vias can be functional vias. In some embodiments, functional vias can be located (moved during the design phase) on the integrated circuit 302 so that the location of a functional via can coincide with a location of a stabilizing via 306.

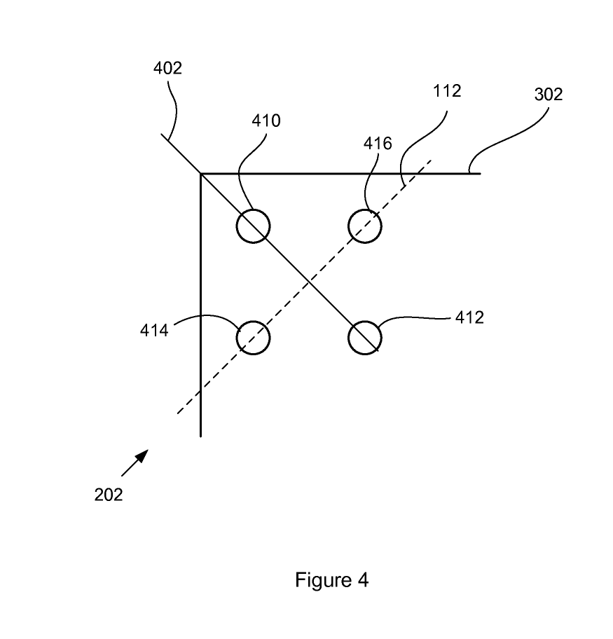

FIG. 4 is a detailed view of fracture region 202 shown in FIG. 3. Fracture line 112 (shown here as a dashed line) can be disposed on any region of the integrated circuit that can yield or break in response to stress or pressures placed on integrated circuit 302. In one embodiment stabilizing vias can be preferentially added along a line normal to the fracture line 112. In FIG. 2B, the line normal to fracture line 112 is normal line 402. FIG. 4 shows four stabilizing vias 410, 412, 414 and 416 in fracture region 202. Normal line 402 is a line drawn at right angles to fracture line 112 and coincident with a corner of the integrated circuit 302.

Although four stabilizing vias 410, 412, 414 and 416 are illustrated in FIG. 4, some embodiments may have more than or fewer than four stabilizing vias. In some embodiments, for example, fewer than four stabilizing vias may be sufficient to support integrated circuit 302. In embodiments with few than four stabilizing vias 306, stabilizing vias 306 can preferentially arranged along normal line 402. For example, if only one stabilizing via 306 is needed, then stabilizing via 410 can be used. If two stabilizing vias 306 are needed, then stabilizing via 410 and 412 can be used. Note that both stabilizing vias 410 and 412 are located on normal line 402. In some embodiments, stabilizing vias 410 and 412 disposed on normal line 402 can offer a relatively greater amount of stability with respect to fracture line 112. If additional stabilizing vias 306 are required, then stabilizing vias 414 and 416 can be added. In one embodiment, additional stabilizing vias can be disposed on either side of normal line 402. In yet other embodiments, the stabilizing vias 410, 412, 414 and 416 within the fracture area 202 can be in patterns (i.e., attachment patterns) instead of the square pattern shown in FIG. 4. For example, stabilizing vias 306 can be arranged in a rectangular, grid, circular or oval attachment pattern.

The number of stabilizing vias 306 needed to add support for any particular fracture region 202 can be a function of integrated circuit thickness 134, width 204, length 208 as well as resin width 206, length 208 and thickness 136. The number of stabilizing vias 306 can also be a function of the particular stabilizing via 306 implementation.

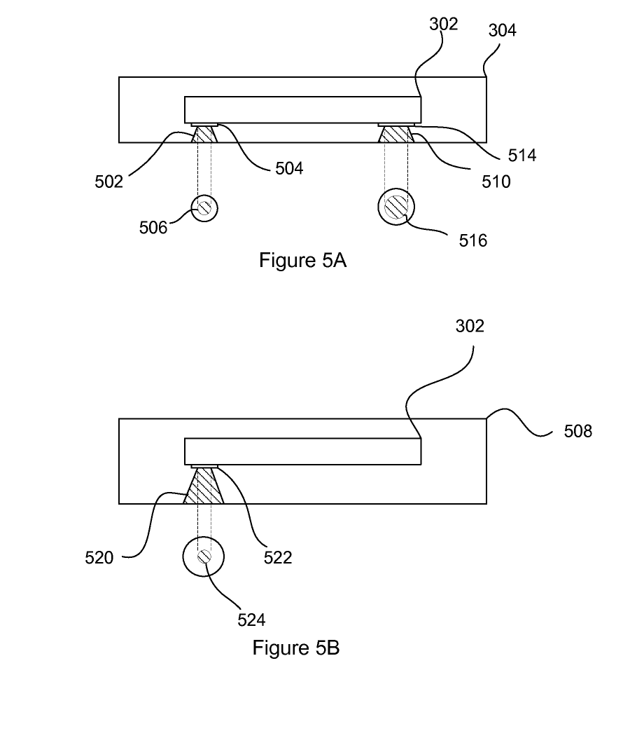

FIGS. 5A and 5B illustrate different stabilizing via physical characteristics. In one embodiment, the stabilizing power of a stabilizing via can be a function of the pad size on the integrated circuit 302. FIG. 5A shows a first stabilizing via 502 shown in resin 304. A first corresponding pad 504 can allow a bond area 506 from the first stabilizing via 502. If a stabilizing via is made to have a relatively greater diameter, then more bond area can result. A second stabilizing via 510 is shown in resin 304. The second stabilizing via 510 can have a relatively larger diameter than the first stabilizing via 502. The relatively larger pad 514 can allow a relatively larger bond area 516. The relatively larger bond area 516 can have more stabilizing power compared to a stabilizing via with relatively less bond area 506.

More than one stabilizing via size can be used on integrated circuit 302. Since, in one embodiment, a relatively larger stabilizing via such as via 510 can have a greater stabilization affect compared to a relatively smaller via, such as via 502, relatively larger vias can be disposed within fracture regions 202. Relatively smaller vias (e.g. via 502) can be used to carry signals to and from integrated circuit 302. In one embodiment, fewer stabilizing vias can be required within a fracture region 202 when relatively larger stabilizing vias are selected.

FIG. 5B illustrates the effect of resin thickness on bond area. Integrated circuit 302 is embedded in resin 508. Resin 508 can be relatively thicker than resin 304. A thicker resin 508 may require a relatively deeper stabilizing via 520 to be formed. In some embodiments, a relatively deeper stabilizing via 520 can result in a relatively smaller bond area 524 on corresponding pad 522.

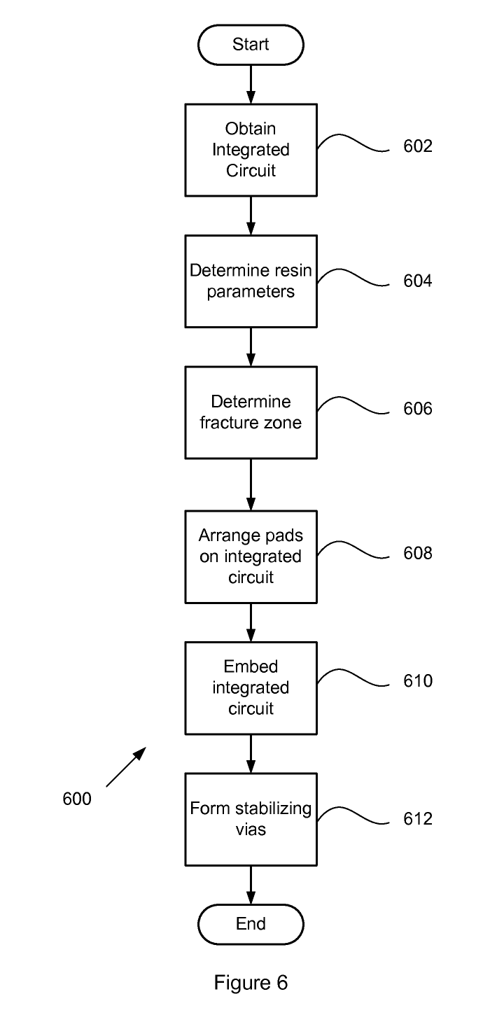

FIG. 6 is a flow chart of method steps 600 for providing stabilizing vias to enhance integrated circuit stability. The method begins in step 602 when an integrated circuit is obtained. The integrated circuit can have a width, length and thickness than can have an associated determined amount of stress that the integrated circuit can bear before failure, by fracture for example.

In step 604, resin parameters are obtained. Resin parameters can include the overall resin length and width as well as the thickness of the resin between the integrated circuit and the outer edges of the resin. In some embodiments, the inherent stiffness of the resin can be determined. There are many resin systems in general, and PCB resin systems in particular that can be selected for resin 104. While any one resin may have particular physical characteristics, the methods described herein can be applied to any resin to increase support of the integrated circuit. In some embodiments, it is desirable to provide a resin that allows the device to have some amount of flexture to avoid fracturing. In other embodiments, it is desirable to provide a resin such that the device is rigid and non-flexible.

In step 606, the combination resin/integrated circuit system is analyzed to determine a fracture zone and probable fracture lines. Fracture zones can be in areas of the integrated circuit that can be subject to relatively higher levels of stress with respect to other areas of the integrated circuit. In some embodiments, a computer simulation program can be used to determine the areas of the integrated circuit that are most susceptible to stress factures given various factors such as the size and shape of the integrated circuit and the size, shape, thickness and type of the resin material given a pre-determined amount of load or force experienced by the combined structure (integrated circuit and resin).

In step 608, pads can be arranged on the integrated circuit within the fracture zones. In one embodiment, pads can be arranged along lines normal to fracture lines within fracture zone. The number of pads and diameter of pads can be determined by how much additional stability can be required as determined in step 606. For example, computer simulation information can be used to determine the number, pattern and thickness of the stabilizing vias to provide the most stabilization in the pre-determined fracture zones. Other factors can include cost considerations and the amount of space that can be used in the integrated circuit to provide for the pads to anchor the stabilizing vias. The integrated circuit is then fabricated with the pad pattern corresponding to the optimized stabilizing via pattern. The pads can be formed of conductive or non-conductive material.

In step 610, the integrated circuit can be embedded in the resin using any of a number of known manufacturing processes. In step 612, stabilizing vias can be formed in the resin. In one embodiment, stabilizing vias can be formed by drilling through the resin to the corresponding pad on the integrated circuit, using for example a laser drilling technique, to create voids that will then be filled. As discussed previously, the stabilizing vias can be functional in that they can carry electrical signals to or from the integrated circuit. In these cases, the voids formed by the drilling can be filled with conductive material such as copper, aluminum, or other suitable conductor. In cases where the stabilizing vias are non-functional, the voids can be filled with a conductive material or non-conductive material.

The various aspects, embodiments, implementations or features of the described embodiments can be used separately of in any combination. Various aspects of the described embodiments can be implemented by software, hardware of a combination of hardware and software. The described embodiments can also be embodied as non-transitory computer readable code on a computer readable medium. For example, as described in the forgoing embodiments, a computer simulation program can be used to determine fracture zones and/or optimal placement of stabilizing vias. The computer readable medium is any data storage device that can store data which can thereafter be read by a computer system. Examples of computer readable medium include read-only memory, random-access memory, CD-ROMs, DVDs, magnetic tape, optical data storage devices and carrier waves. The computer readable medium can also be distributed over network-coupled computer systems so that the computer readable code is stored and executed in a distributed fashion.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of specific embodiments are presented for purposes of illustration and description. They are not intended to be exhaustive or to limit the described embodiments to the precise forms disclosed. It will be apparent to one of ordinary skill in the art that many modifications and variations are possible in view of the above teachings.

What is claimed is:

1. A method of stabilizing an integrated circuit embedded in a substrate, the method comprising:
determining an attachment pattern corresponding to the location of at least one stabilizing via for providing stabilization within at least one fracture zone on the integrated circuit, the at least one fracture zone based on the physical and material characteristics of the integrated circuit and the substrate;
disposing at least one pad on the integrated circuit according to the determined attachment pattern, the at least one pad corresponding to the location of the at least one stabilizing via;
embedding the integrated circuit within the substrate, wherein the substrate surrounds and envelops all sides of the integrated circuit;
forming at least one void through the substrate to the at least one pad; and
forming the at least one stabilizing via by filing the at least one void with a via material thereby anchoring the at least one fracture zone to the substrate.

2. The method of claim 1, wherein the at least one fracture zone includes a fracture line in proximity to a corner of the integrated circuit and the attachment pattern corresponds to providing the at least one stabilizing via along a line substantially normal to the fracture line.

3. The method of claim 2, wherein the attachment pattern corresponds to providing two stabilizing vias along the line substantially normal to the fracture line.

4. The method of claim 2, wherein the attachment pattern corresponds to providing one stabilizing via along the line substantially normal to the fracture line.

5. The method of claim 2, wherein the attachment pattern corresponds to providing three or more stabilizing vias along the line substantially normal to the fracture line.

6. The method of claim 2, wherein the attachment pattern corresponds to providing at least one additional stabilizing via within the at least one fracture zone but not along the line substantially normal to fracture line.

7. The method of claim 1, wherein the attachment pattern corresponds to one of a square, grid, rectangular, circular or oval pattern within the at least one fracture zone.

8. The method of claim 1, wherein the at least one stabilizing via is a non-functional via that does not carry electrical signals to or from the integrated circuit.

9. The method of claim 1, wherein the via material is a conductive material.

10. The method of claim 1, wherein the insulating portion of the printed circuit board is comprised of resin.

11. The method of claim 1, wherein determining the attachment pattern comprises using a computer simulation program to determine the number, pattern and thickness of the at least one stabilizing via to optimize stabilization in the at least one fracture zone.

12. The method of claim 1, wherein forming at least one void through the insulating portion of the printed circuit board to the disposed pads comprises a laser drilling procedure.

13. An embedded integrated circuit device comprising:
an integrated circuit having at least one pad disposed thereon, the at least one pad located within at least one fracture zone of the integrated circuit;
a resin, wherein the resin surround and envelopes all sides of the integrated circuit; and
at least one stabilizing via disposed in the resin between the at least one pad and an outer surface of the resin, wherein the stabilizing via is configured to couple the integrated circuit to the resin and anchor the at least one fracture zone to the resin.

14. The method of claim 13, wherein the at least one fracture zone includes a fracture line in proximity to a corner of the integrated circuit and the at least one pad is located along a line substantially normal to fracture line.

15. The method of claim 14, wherein two pads are located along a line substantially normal to the fracture line resulting in two stabilizing vias disposed along the line substantially normal to the fracture line.

16. The method of claim 2, wherein one pad is located along a line substantially normal to the fracture line resulting in one stabilizing via disposed along the line substantially normal to the fracture line.

17. The method of claim 2, wherein three or more pads are located along a line substantially normal to the fracture line resulting in three or more stabilizing vias disposed along the line substantially normal to the fracture line.

18. The method of claim 2, wherein at least one additional pad is located within the fracture zone but not along a line substantially normal to the fracture line resulting in at least one additional stabilizing via disposed within the fracture zone but not along a line substantially normal to the fracture line.

19. The method of claim 1, wherein the at least one pad is located on the integrated circuit in a pattern corresponding to one of a square, grid, rectangular, circular or oval pattern within the at least one fracture zone.

20. The method of claim 1, wherein the at least one stabilizing via is a non-functional via that does not carry electrical signals to or from the integrated circuit.

21. The method of claim 1, wherein the stabilizing via material comprises a conductive material.

22. The method of claim 1, wherein the insulating portion of the printed circuit board is comprised of resin.

23. The method of claim 1, wherein the stabilizing via comprises a conductive material.

24. A non-transitory computer readable medium for storing computer program code executed by a processor for determining fracture zones in a integrated circuit device, the integrated circuit device comprising a resin and an integrated circuit embedded therein, the computer readable medium comprising computer program code for:
accepting data corresponding to the size and shape of an integrated circuit;
accepting data corresponding to the size, shape and material characteristics of the resin; and
simulating a predetermined force placed upon the integrated circuit device to determine at least one fracture zone of the integrated circuit.

25. The method of claim 24, further comprising computer program code for determining optimal locations on the integrated circuit device for forming stabilizing vias in order to reduce the probability of fracturing the integrated circuit device at the at least one fracture zone.
